(19) United States
(12) Patent Application Publication
(10) Pub. No.: US 2025/0222494 A1
(43) Pub. Date: Jul. 10, 2025

(54) VIBRATING BODY AND SUBSTRATE PROCESSING APPARATUS

(71) Applicant: SHIBAURA MECHATRONICS CORPORATION, Yokohama-shi (JP)

(72) Inventors: Masaya KAMIYA, Yokohama-shi (JP); Kensuke DEMURA, Yokohama-shi (JP); Satoshi NAKAMURA, Yokohama-shi (JP); Minami NAKAMURA, Yokohama-shi (JP)

(73) Assignee: SHIBAURA MECHATRONIS CORPORATION, Yokohama-shi (JP)

(21) Appl. No.: 19/093,712

(22) Filed: Mar. 28, 2025

Related U.S. Application Data
(63) Continuation of application No. PCT/JP2023/035170, filed on Sep. 27, 2023.

(30) Foreign Application Priority Data
Sep. 29, 2022 (JP) 2022-155802

(51) Int. Cl. B08B 3/12; B08B 7/00; B08B 13/00; H01L 21/67; H01L 21/687

(52) U.S. Cl. CPC B08B 3/123; B08B 7/0092; B08B 13/00; H01L 21/67051; H01L 21/68764

(57) ABSTRACT

A vibrating body according to an embodiment is used for cleaning a substrate. A contact portion of the vibrating body with a liquid on a surface of the substrate has an inclined region inclined with respect to an end portion of the vibrating body facing the substrate. An angle between the inclined region and an extension line of the end portion of the vibrating body is θ, which satisfies the following condition: 20 degrees≤θ≤87 degrees

### CROSS-REFERENCE TO RELATED APPLICATION

The application is a Bypass Continuation application of PCT International Application No. PCT/JP2023/035170, filed on Sep. 27, 2023 and designating the United States, the international application being based upon and claiming the benefit of priority from Japanese Patent Application No. 2022-155802, filed on Sep. 29, 2022, the entire content of which is incorporated herein by reference.

### TECHNICAL FIELD

The present disclosure relates to a vibrating body and a substrate processing apparatus.

### BACKGROUND

As a method of removing contaminants such as particles adhering to a surface of a substrate such as an imprint template, a photolithography mask, or a semiconductor wafer, a freeze cleaning method or a spin cleaning method has been proposed.

In the freeze cleaning method, in general, pure water is used as a liquid used for cleaning. For example, in the freeze cleaning method, the pure water and a cooling gas are first supplied to a surface of a rotating substrate. Subsequently, the supply of the pure water is stopped, and a portion of the supplied pure water is discharged to form a water film on the surface of the substrate. The water film is frozen by the supplied cooling gas. When the water film is frozen and an ice film is formed, contaminations such as particles are taken into the ice film and separated from the surface of the substrate. Subsequently, the pure water is supplied to the ice film to melt the ice film, and the contaminations are discharged together with the pure water to the outside of the substrate by a centrifugal force.

In the spin cleaning method, by supplying a cleaning liquid to a surface of a rotating substrate, contaminants are discharged together with the cleaning liquid to the outside of the substrate by a centrifugal force.

By performing the freeze cleaning method or the spin cleaning method, it is possible to increase a removal rate of contaminants. However, in recent years, further improvement of the removal rate of contaminants has been required.

Here, as a result of examination of the present inventors, it was confirmed that, in the freeze cleaning method, when melting the ice film by supplying the pure water to the ice film, it might be difficult for the contaminants taken into the ice film to move in a direction parallel to the surface of the substrate. Further, it was confirmed that, in the spin cleaning method, when supplying the cleaning liquid to the surface of the substrate, it might be difficult for the contaminants adhering to the surface of the substrate to move in a direction parallel to the surface of the substrate. When it is difficult for the contaminants to move in the direction parallel to the surface of the substrate, it is difficult to improve a removal rate of contaminants.

### SUMMARY

Various embodiments of the present disclosure provide a vibrating body and a substrate processing apparatus, which facilitate movement of contaminants in a direction parallel to a surface of a substrate.

A vibrating body according to an embodiment is used for cleaning a substrate. A contact portion of the vibrating body with a liquid on a surface of the substrate has an inclined region inclined with respect to an end portion of the vibrating body facing the substrate. An angle between the inclined region and an extension line of the end portion of the vibrating body is θ, which satisfies the following condition: 20 degrees≤θ≤87 degrees.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view illustrating a substrate processing apparatus according to a first embodiment.

FIG. 2 is a schematic perspective view of a vibrating body.

FIG. 3 is a schematic view illustrating an operation of a vibrating body according to a comparative example.

FIG. 4 is a schematic view illustrating a side surface of a groove.

FIG. 5 is a graph illustrating a relationship between an angle and an emission rate of vibration.

FIG. 6 is a schematic perspective view of a vibrating body according to another embodiment.

FIG. 7 is a schematic cross-sectional view illustrating an operation of the vibrating body.

FIG. 8 is a schematic perspective view illustrating a vibrating body according to another embodiment.

FIG. 9 is a timing chart illustrating an operation of the substrate processing apparatus.

FIG. 10 is a graph illustrating a change in temperature of liquid supplied to a front surface of a substrate.

FIG. 11 is a schematic view illustrating a substrate processing apparatus according to a second embodiment.

FIG. 12 is a schematic view illustrating a substrate processing apparatus according to a third embodiment.

FIG. 13 is a schematic view illustrating a side surface of a groove provided in the vibrating body.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments are illustrated with reference to the drawings. In addition, like elements are designated by like reference numerals in each drawing, and detailed descriptions are appropriately omitted.

In addition, a substrate 100 illustrated below may be, for example, a semiconductor wafer, an imprint template, a photolithography mask, a plate-shaped body used in micro electro mechanical systems (MEMS), or the like. Further, the substrate 100 is not limited to those exemplified above.

In addition, unevenness as a pattern may or may not be formed on a surface of the substrate 100. The substrate 100 on which unevenness is not formed may be, for example, a substrate (bulk substrate) before the unevenness is formed, or the like.

### (Substrate Processing Apparatus According to First Embodiment)

A substrate processing apparatus according to a first embodiment may be used, for example, when performing freeze cleaning for the substrate 100. The substrate processing apparatus may supply a cooling gas to a front surface (e.g., a surface on which a liquid film to be described later is formed) of the substrate 100, may supply a cooling gas to a rear surface (e.g., a surface opposite to the surface on which the liquid film is formed) of the substrate 100, or may supply a cooling gas to both the front surface and the rear surface of the substrate 100.

Hereinafter, as an example, a substrate processing apparatus 1 that supplies a cooling gas to the rear surface of the substrate 100 is described.

In addition, in this specification, a film of a liquid 101 formed on a front surface 100b (corresponding to an example of a first surface) of the substrate 100 is referred to as a liquid film.

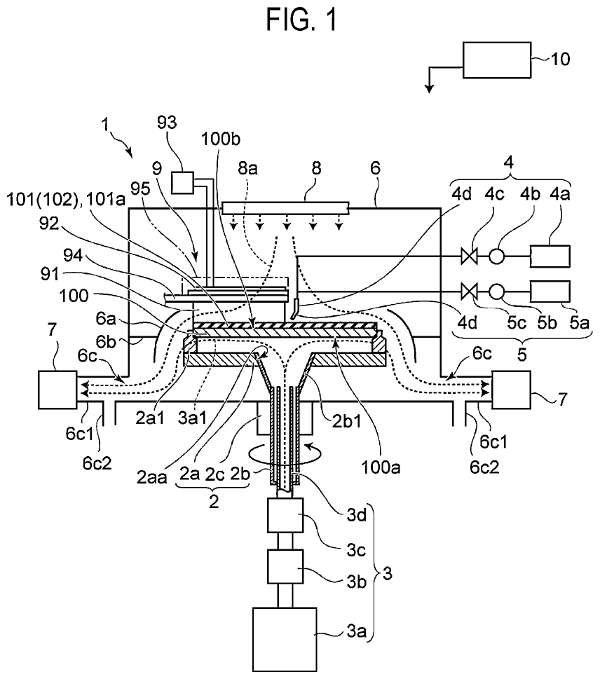

FIG. 1 is a schematic view illustrating a substrate processing apparatus 1 according to a first embodiment.

As illustrated in FIG. 1, the substrate processing apparatus 1 includes, for example, a stage 2, a cooler 3, a first liquid supply 4, a second liquid supply 5, a chamber 6, an exhauster 7, an air blower 8, a vibration generator 9, and a controller 10.

The stage 2 rotates the substrate 100 placed thereon. The stage 2 includes, for example, a placement table 2a, a rotary shaft 2b, and a drive 2c.

The placement table 2a is rotatably provided inside the chamber 6. The placement table 2a has a plate shape. A plurality of supports 2a1 for supporting the substrate 100 is provided on one main surface of the placement table 2a. When supporting the substrate 100 by the plurality of supports 2a1, the front surface 100b (a surface on which cleaning is performed) of the substrate 100 faces a side opposite to the placement table 2a.

Further, a hole 2aa penetrating the placement table 2a in a thickness direction is provided in a central portion of the placement table 2.

One end portion of the rotary shaft 2b is provided on an inner wall of the hole 2aa of the placement table 2a. The other end portion of the rotary shaft 2b is provided outside the chamber 6. The rotary shaft 2b is connected to the drive 2c at a location outside the chamber 6.

The rotary shaft 2b has a cylindrical shape. A nozzle 2b1 is provided at an end portion of the rotary shaft 2b on a side of the placement table 2a. The nozzle 2b1 is open in a surface of the placement table 2a, on which the plurality of supports 2a1 is provided. An end portion of the nozzle 2b1 on a side of the opening is connected to the inner wall of the hole 2aa. The opening of the nozzle 2b1 faces a rear surface 100a (corresponding to an example of a second surface) of the substrate 100 placed on the placement table 2a. A cross-sectional area of the nozzle 2b1 in a direction orthogonal to a central axis of the rotary shaft 2b increases toward the placement table 2b (toward the opening).

By providing the nozzle 2b1, a cooling gas 3a1 emitted therefrom can be supplied to a wider region in the rear surface 100a of the substrate 100. Further, an emission speed of the cooling gas 3a1 can be reduced. Therefore, it is possible to suppress a supercooled state of the liquid 101 to be described later from becoming hard to be generated due to partially cooling the substrate 100 or an excessively rapid cooling speed of the substrate 100.

A cooling nozzle 3d is attached to an end portion of the rotary shaft 2b on an opposite side to the placement table 2a. A rotary shaft seal, which is not illustrated, is provided between the end portion of the rotary shaft 2b on the opposite side to the placement table 2a and the cooling nozzle 3d. Therefore, the end portion of the rotary shaft 2b on the opposite side to the placement table 2a is sealed airtightly.

The drive 2c is provided outside the chamber 6. The drive 2c is connected to the rotary shaft 2b. A rotation force of the drive 2c is transmitted to the placement table 2a via the rotary shaft 2b. Therefore, the placement table 2b, and further, the substrate 100 placed on the placement table 2a, can be rotated by the drive 2c.

Further, the drive 2c can change a rotation number (rotational speed) in addition to start and stop of rotation. The drive 2c may be provided with, for example, a control motor such as a servo motor.

The cooler 3 supplies the cooling gas 3a1 for cooling the liquid 101 on the front surface 100b of the substrate 100. The cooler 3 supplies the cooling gas 3a1 into a space between the placement table 2a and the rear surface 100a of the substrate 100. The cooler 3 includes, for example, a cooling liquid accommodator 3a, a filter 3b, a flow rate controller 3c, and the cooling nozzle 3d. The cooling liquid accommodator 3a, the filter 3b, and the flow rate controller 3c are provided outside the chamber 6.

The cooling liquid accommodator 3a accommodates a cooling liquid and generates the cooling gas 3a1. The cooling liquid is generated by liquefying the cooling gas 3a1. The cooling gas 3a1 is not particularly limited as long as the cooling gas 3a1 is a gas that hardly react with a material of the substrate 100. The cooling gas 3a1 may be, for example, an inert gas such as nitrogen gas, helium gas, or argon gas.

The cooling liquid accommodator 3a include a tank that accommodates the cooling liquid and an evaporator that evaporates the cooling liquid accommodated in the tank. The tank is provided with a cooling device that maintains a temperature of the cooling liquid. The evaporator generates the cooling gas 3a1 from the cooling liquid by increasing the temperature of the cooling liquid. For example, the evaporator may use an outside air temperature or may perform heating using a heat medium. A temperature of the cooling gas 3a1 may be a temperature equal to or lower than a freezing point of the liquid 101, and may be, for example, −170 degrees C.

In addition, the cooling gas 3a1 may be generated by cooling an inert gas such as nitrogen gas in a chiller or the like. With this configuration, it is possible to simplify the cooling liquid accommodator.

The filter 3b is connected to the cooling liquid accommodator 3a via a pipe. The filter 3b suppresses contaminants such as particles contained in the cooling liquid from flowing out to the substrate 100.

The flow rate controller 3c is connected to the filter 3b via a pipe. The flow rate controller 3c controls a flow rate of the cooling gas 3a1. The flow rate controller 3c may be, for example, a mass flow controller (MFC) or the like. Further, the flow rate controller 3c may indirectly control the flow rate of the cooling gas 3a1 by controlling a supply pressure of the cooling gas 3a1. In this case, the flow rate controller 3c may be, for example, an auto pressure controller (APC) or the like.

The temperature of the cooling gas 3a1 generated from the cooling liquid in the cooling liquid accommodator 3a is set to a substantially predetermined temperature. Therefore, by controlling the flow rate of the cooling gas 3a1 by the flow rate controller 3c, the temperature of the substrate 100, and further, a temperature of the liquid 101 on the front surface 100b of the substrate 100, can be controlled. In this case, by controlling the flow rate of the cooling gas 3a1 by the flow rate controller 3c, it is possible to generate the supercooled state of the liquid 101 in a cooling process to be described later.

The cooling nozzle 3d has a cylindrical shape. One end portion of the cooling nozzle 3d is connected to the flow rate controller 3c. The other end portion of the cooling nozzle 3d is provided inside the rotary shaft 2b. The other end portion of the cooling nozzle 3d is located in a vicinity of an end portion of the nozzle 2b1 on an opposite side to the placement table 2a (on an opposite side of the opening).

The cooling nozzle 3d supplies the cooling gas 3a1 having a flow rate controlled by the flow rate controller 3c to the substrate 100. The cooling gas 3a1 emitted from the cooling nozzle 3d is supplied directly to the rear surface 100a of the substrate 100 via the nozzle 2b1.

In addition, as described above, the substrate processing apparatus may supply the cooling gas 3a1 to the front surface 100b of the substrate 100, or may supply the cooling gas 3a1 to the front surface 100b and the rear surface 100a of the substrate 100. When supplying the cooling gas 3a1 to the front surface 100b of the substrate 100, the cooling nozzle 3d may be provided to face the front surface 100b of the substrate 100.

When the cooling gas 3a1 is supplied to the front surface 100b of the substrate 100, freezing is started from a surface of the liquid film formed on the front surface 100b of the substrate 100. When the freezing is started from the surface of the liquid film, it becomes difficult to separate contaminants adhering to the front surface 100b of the substrate 100 from the front surface 100b of the substrate 100.

Therefore, in order to improve a removal rate of the contaminants, the substrate processing apparatus 1 may supply the cooling gas 3a1 to the rear surface 100a of the substrate 100.

The first liquid supply 4 supplies the liquid 101 to the front surface 100b of the substrate 100. The liquid 101 is used in a preliminary process and a liquid film forming process, which will be described later. The liquid 101 is not particularly limited as long as the liquid 101 hardly reacts with a material of the substrate 100. For example, the liquid 101 may be water (e.g., pure water, ultrapure water, or the like), a liquid having water as a principal ingredient, a liquid in which a gas is dissolved, or the like.

The first liquid supply 4 includes, for example, a liquid accommodator 4a, a supply 4b, a flow rate controller 4c, and a liquid nozzle 4d. The liquid accommodator 4a, the supply 4b, and the flow rate controller 4c are provided outside the chamber 6.

The liquid accommodator 4a accommodates the liquid 101. The liquid 101 having a temperature higher than a freezing point thereof is accommodated in the liquid accommodator 4a. The temperature of the liquid 101 accommodated in the liquid accommodator 4a is, for example, the room temperature (e.g., 20 degrees C.).

The supply 4b is connected to the liquid accommodator 4a via a pipe. The supply 4b supplies the liquid 101 accommodated in the liquid accommodator 4a toward the liquid nozzle 4d. The supply 4b may be, for example, a pump having a resistance to the liquid 101, or the like.

The flow rate controller 4c is connected to the supply 4b via a pipe. The flow rate controller 4c controls a flow rate of the liquid 101 supplied by the supply 4b. The flow rate controller 4c may be, for example, a flow rate control valve. Further, the flow rate controller 4c may start and stop the supply of the liquid 101.

The liquid nozzle 4d is provided inside the chamber 6. The liquid nozzle 4d has a cylindrical shape. One end portion of the liquid nozzle 4d is connected to the flow rate controller 4c via a pipe.

The other end portion (a discharge side of the liquid 101) of the liquid nozzle 4d is provided above the front surface 100b of the substrate 100 placed on the placement table 2a. The liquid 101 discharged from the liquid nozzle 4d is supplied to the front surface 100b of the substrate 10. The other end portion of the liquid nozzle 4d may be provided in a vicinity of a rotational center of the substrate 100. With this configuration, it is possible to supply the liquid 101 to a substantially center of the front surface 100b of the substrate 100. The liquid 101 supplied to the substantially center of the front surface 100b of the substrate 100 is diffused toward a periphery of the front surface 100b of the substrate 100, so that a liquid film having a substantially constant thickness is formed on the front surface 100b of the substrate 100.

Further, as illustrated in FIG. 1, an opening (discharge port) of the other end portion of the liquid nozzle 4d may face a side surface of a vibrating body 91 (a main body 91a) to be described later on a side of the rotational center of the substrate 100. With this configuration, the liquid 101 discharged from the liquid nozzle 4d is brought into contact with the side surface of the vibrating body 91 (the main body 91a) on the side of the rotational center of the substrate 100, and then is supplied to the front surface 100b of the substrate 100. Therefore, the liquid 101 may be supplied to a wider region in the front surface 100b of the substrate 100, or a collision speed of the liquid 101 with the substrate 100 may be reduced. As a result, it becomes easy to form the liquid film on the entire front surface 100b of the substrate 100.

The second liquid supply 5 supplies a liquid 102 to the front surface 100b of the substrate 100. The liquid 102 is used in a thawing process to be described later. Therefore, the liquid 102 may hardly react with the material of the substrate 100 and hardly remain on the front surface 100b of the substrate 100 in a drying process to be described later. Like the liquid 101 described above, the liquid 102 may be, for example, water (e.g., pure water, ultrapure water, or the like), a liquid having water as a principal ingredient, a liquid in which a gas is dissolved, or the like.

In this case, the liquid 102 may be the same as the liquid 101 or may be different from the liquid 101. When the liquid 102 is the same as the liquid 101, the second liquid supply 5 may be omitted. When the second liquid supply 5 is omitted, the first liquid supply 4 is used even in the thawing process to be described above. That is, the liquid 101 is used even in the thawing process.

In addition, a temperature of the liquid 102 may be set to a temperature higher than the freezing point of the liquid 101. For example, the temperature of the liquid 102 may be a temperature that can thaw the frozen liquid. The temperature of the liquid 102 is, for example, about the room temperature (e.g., 20 degrees C.). Further, when the temperature of the liquid 102 is set to a temperature exceeding the room temperature, it is possible to promote reduction in thawing time. When the temperature of the liquid 102 is set to a temperature exceeding the room temperature, for example, a heater and a temperature control device are provided in a liquid accommodator 5a to be described later.

In addition, when the liquid 101 is used even in the thawing process and the temperature of the liquid 101 is set to a temperature exceeding the room temperature, a temperature of a liquid film formed before a cooling process to be described later increases. When the temperature of the liquid film increases, a time required for the cooling process is lengthened. Therefore, in a case in which the temperature of the liquid used in the thawing process is set to a temperature exceeding the room temperature, even when the liquid 102 is the same as the liquid 101, the second liquid supply 5 may be provided.

The second liquid supply 5 includes, for example, the liquid accommodator 5a, a supply 5b, a flow rate controller 5c, and the liquid nozzle 4d.

The liquid accommodator 5a may have the same configuration as the liquid accommodator 4a described above. The supply 5b may have the same configuration as the supply 4b described above. The flow rate controller 5c may have the same configuration as the flow rate controller 4c described above.

In addition, in FIG. 1, a case where the first liquid supply 4 and the second liquid supply 5 commonly use the nozzle 4d is exemplified. However, a liquid nozzle that supplies the liquid 101 and a liquid nozzle that supplies the liquid 102 may be provided separately from each other. Further, a hole through which the liquid 101 and the liquid 102 flow is provided in the vibrating body 91 to be described later, thereby integrating the vibrating body 91 and the liquid nozzle.

Hereinafter, a case where the liquid nozzle 4d is commonly used in supplying the liquid 101 and supplying the liquid 102 will be described.

The chamber 6 has a box shape. A cover 6a is provided inside the chamber 6. The cover 6a receives the liquid 101 or 102 that is supplied to the substrate 100 and discharged to the outside of the substrate 100 by the rotation of the substrate 100. A partition plate 6b is provided inside the chamber 6. The partition plate 6b is provided between an outer surface of the cover 6a and an inner surface of the chamber 6.

A plurality of discharge ports 6c is provided in lower side surfaces of the chamber 6. The cooling gas 3a1, the liquid 101, the liquid 102, and air 8a supplied by the air blower 8, which have been used, are discharged from the discharge ports 6c to the outside of the chamber 6. An exhaust pipe 6cl is connected to the discharge ports 6c. Further, a discharge pipe 6c2 that discharges the liquid 101 and the liquid 102 is connected to the discharge ports 6c.

The exhauster 7 is connected to the exhaust pipe 6c1. The exhauster 7 exhausts the cooling gas 3a1 and the air 8a, which have been used. The exhauster 7 is, for example, a pump, a blower, or the like.

The air blower 8 is provided in a ceiling surface of the chamber 6. Further, the air blower 8 may be provided in a side surface of the chamber 6, as long as the air blower 8 is located on a side of a ceiling. The air blower 8 includes, for example, an air blower such as a fan and a filter. The filter is, for example, a high efficiency particulate air filter (HEPA filter), or the like.

The vibration generator 9 is used in the thawing process which will be described later. The vibration generator 9 transmits vibrations to a liquid on the front surface 100b of the substrate 100. In this case, the vibration generator 9 transmits vibrations to the liquid on the front surface 100b of the substrate 100 from a direction intersecting the front surface 100b of the substrate 100. In the thawing process, the liquid on the front surface 100b of the substrate 100 is the supplied liquid 102, the liquid 101 generated by dissolution of a frozen film 101a which will be described later, or the like.

The vibration generator 9 includes, for example, the vibrating body 91, a vibrator 92, a circuit 93, a holder 94, and a cover 95.

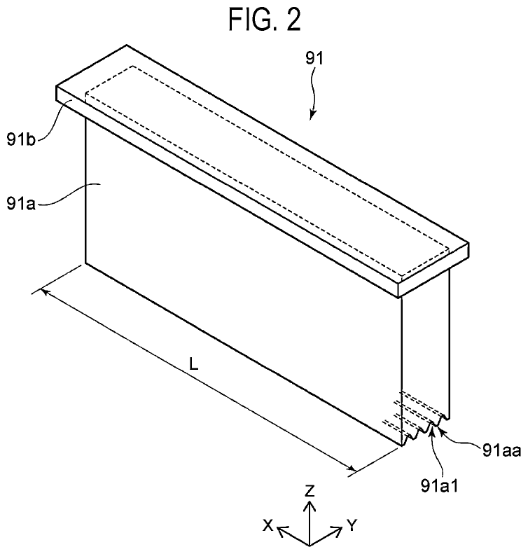

FIG. 2 is a schematic perspective view of the vibrating body 91.

In addition, arrows X, Y, and Z in FIG. 2 represent three directions orthogonal to one another. Further, an X direction is a horizontal direction, and a Y direction is a horizontal direction orthogonal to the X direction.

As illustrated in FIG. 2, the vibrating body 91 includes, for example, a main body 91a and a flange 91b. The main body 91a and the flange 91b are formed as a single body. The vibrating body 91 is formed of a material that easily propagates vibrations from the vibrator 92 and hardly generates particles. The vibrating body 91 is formed of, for example, quartz.

The main body 91a has, for example, a rectangular parallelepiped shape. A dimension L of the main body 91a in the X direction may be greater than a maximum dimension between the rotational center of the substrate 100 and a periphery of the substrate 100. For example, when a planar shape of the substrate 100 is a circle, the dimension L of the main body 91a may be greater than a radius of the substrate 100. For example, when the planar shape of the substrate 100 is a quadrangle, the dimension L of the main body 91a may be greater than a half of a diagonal dimension of the substrate 100.

In the thawing process to be described later, the substrate 100 is rotating. Therefore, when the dimension L of the main body 91a is greater than the maximum dimension between the rotational center of the substrate 100 and the periphery of the substrate 100, it is possible to transmit, while performing the thawing process, the vibrations to the liquid on the entire front surface 100b of the substrate 100 without moving the vibrating body 91.

In addition, a groove 91a1 is formed at an end portion 91aa of the main body 91a on a side of the substrate 100 (on a side of the placement table 2a). At least one groove 91a1 may be provided. The groove 91a1 extends in the X direction. In the X direction, the groove 91a1 is open in both side surfaces of the main body 91a. When a plurality of grooves 91a1 is provided, the plurality of grooves 91a1 may be provided side by side in the Y direction.

The flange 91b has a plate shape, and is provided at a side opposite to the end portion 91aa of the main body 91a. The flange 91b protrudes from the side surface of the main body 91a. The flange 91b may be in contact with an upper surface of the holder 94. The flange 91b may be omitted. However, when the flange 91b is provided, it becomes easy to position the vibrating body 91 or stabilize a posture of the vibrating body 91 when attaching the vibrating body 91 to the holder 94.

Next, an operation and an effect of the vibrating body 91 will be described.

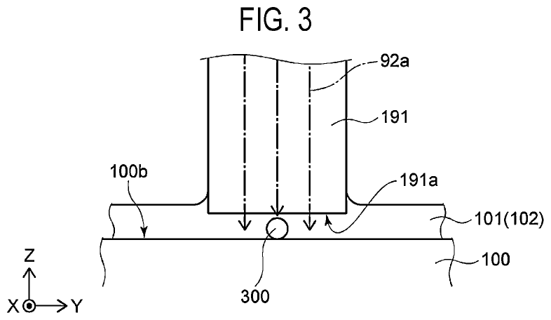

FIG. 3 is a schematic view illustrating an operation of a vibrating body 191 according to a comparative example.

In addition, arrows X, Y, and Z in FIG. 3 are the same as in FIG. 2.

As illustrated in FIG. 3, an end portion 191a of the vibrating body 191 on a side of the substrate 100 is a flat surface. The end portion 191a is parallel to the front surface 100b of the substrate 100. When vibrations 92a from the vibrator 92 propagate inside the vibrating body 191 and are incident to the end portion 191a, the vibrations 92a propagate from the vibrating body 191 to the liquid 101 or 102 on the front surface 100b of the substrate 100 while a propagation direction of the vibrations 92a does not change substantially. Therefore, it becomes easy that a force in a direction (Z direction) pressing the front surface 100b of the substrate acts on contaminants 300 adhering to the front surface 100b of the substrate 100 or contaminants 300 floating in the liquid 101 or 102 on the front surface 100b of the substrate 100. When the force in the direction pressing the front surface 100b of the substrate 100 acts on the contaminants 300, it becomes difficult that the contaminants 300 move in a direction parallel to the front surface 100b of the substrate 100. Therefore, it becomes difficult to improve a removal rate of the contaminants 300.

Accordingly, a contact portion of the vibrating body 91 with the liquid 101 or 102 on the front surface 100b of the substrate 100 has a region inclined with respect to the end portion 91aa of the vibrating body 91. Further, when performing the thawing process to be described later, the end portion 91aa of the vibrating body 91 becomes substantially parallel to the front surface 100b of the substrate 100. Therefore, the region inclined with respect to the end portion 91aa of the vibrating body 91 is a region inclined with respect to the front surface 100b of the substrate 100.

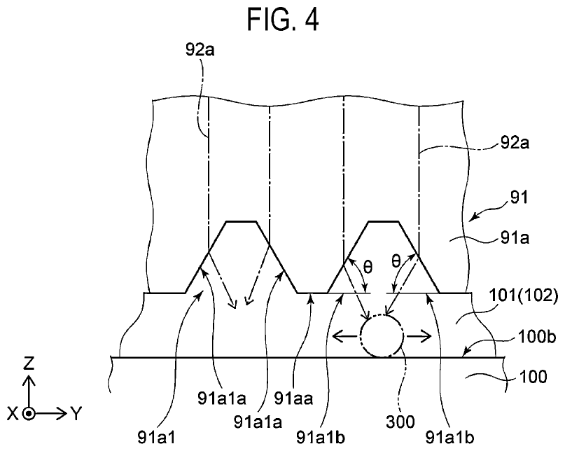

For example, as illustrated in FIG. 4, the groove 91a1 having an inclined side surface 91a1a is provided in the end portion 91aa of the vibrating body 91 at the substrate 100 (the main body 91a).

FIG. 4 is a schematic view illustrating the side surface 91a1a of the groove 91a1.

In addition, arrows X, Y, and Z in FIG. 4 are the same as in FIG. 2.

As illustrated in FIG. 4, the side surface 91a1a of the groove 91a1 in the Y direction is inclined with respect to the end portion 91aa. Further, one side surface 91a1a is inclined in a reverse direction with respect to a side surface 91a1a that faces the one side surface 91a1a.

As illustrated in FIG. 4, in the vibrating body 91 according to the present embodiment, the vibrations 92a from the vibrator 92 propagate inside the vibrating body 191 (the main body 91a) and are incident to the side surface 91a1a of the groove 91a1. A propagation direction of the vibrations 92a incident onto the side surface 91a1a in the liquid 101 or 102 on the front surface 100b of the substrate 100 changes according to an inclined angle of the side surface 91a1a.

Therefore, as illustrated in FIG. 4, a direction of the force that acts on the contaminants 300 easily becomes a direction inclined with respect to the front surface 100b of the substrate 100. When a force in the direction inclined with respect to the front surface 100b of the substrate 100 is applied to the contaminants 300, a component force in the direction parallel to the front surface 100b of the substrate 100 acts on the contaminants 300. Therefore, the contaminants 300 easily move in the direction parallel to the front surface 100b of the substrate 100. When the contaminants 300 easily move in the direction parallel to the front surface 100b of the substrate 100, it is possible to increase the removal rate of the contaminants 300.

In addition, in FIG. 4, a case where a contour of a cross-section of the groove 91a1 is a trapezoid is illustrated, but the contour of the cross-section of the groove 91a1 may be, for example, a triangle. Further, the side surface of the groove 91a1 may be a flat surface or a curved surface. When the side surface of the groove 91a1 is the curved surface, an angle between a tangent of the curved surface and an extension line of the end portion 91aa of the vibrating body 91 is set to θ.

When the groove 91a1 having an inclined surface is provided in the end portion 91aa of the vibrating body 91, the inclined surface (e.g., the side surface 91a1a) of the groove 91a1 is in contact with the liquid 101 or 102, and becomes a region inclined with respect to the end portion 91aa of the vibrating body 91.

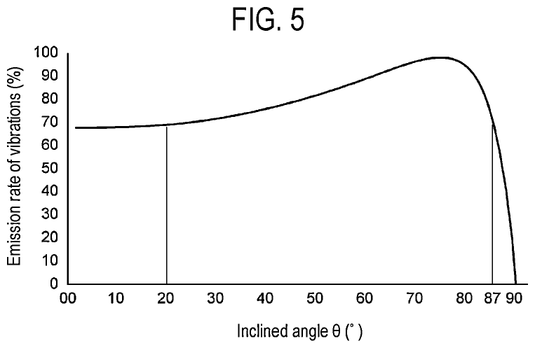

FIG. 5 is a graph illustrating a relationship between the angle θ and an emission rate of vibrations.

The emission rate of vibrations is “(energy of vibrations emitted from the vibrating body 91/energy of vibrations emitted from the vibrator 92)×100(%).”

As can be recognized from FIG. 5, when “20 degrees≤θ≤87 degrees,” it is possible to efficiently transmit the vibrations 92a from the vibrator 92 to the liquid 101 or 102. Accordingly, since the contaminants 300 more easily move in the direction parallel to the front surface 100b of the substrate 100, it is possible to further improve the removal rate of the contaminants 300.

In addition, as illustrated in FIG. 4, the angle θ is an angle between the side surface 91a1a of the inclined region (the groove 91a1) and an extension line 91a1b of the end portion 91aa of the vibrating body 91.

Next, referring back to FIG. 1, the vibrator 92, the circuit 93, the holder 94, and the cover 95, which are provided in the vibration generator 9, will be described.

The vibrator 92 is provided on the vibrating body 91 (the flange 91b). The vibrator 92 may adhere to, for example, the vibrating body 91. The vibrator 92 converts an applied voltage into a force. The vibrator 92 is, for example, a piezoelectric element or the like.

The circuit 93 is electrically connected to the vibrator 92. The circuit 93 applies a voltage having a predetermined frequency to the vibrator 92. In this case, the frequency is, for example, about 1.6 MHz to about 4 MHz.

The holder 94 holds the vibrating body 91 at a predetermined position above the substrate 100. In this case, a distance between the end portion 91aa of the vibrating body 91 (the main body 91a) and the front surface 100b of the substrate 100 may be set to 1.8 mm or less. With this configuration, the liquid 101 or 102 is easily held between the end portion 91aa of the vibrating body 91 (the main body 91a) and the front surface 100b of the substrate 100. Thus, it is possible to efficiently transmit vibrations from the vibrating body 91 (the main body 91a) to the liquid 101 or 102.

The holder 94 has a hole having, for example, a plate shape and penetrating the holder 94 in a thickness direction. The main body 91a of the vibrating body 91 may be inserted into the hole. When the main body 91a is inserted into the hole, the flange 91b of the vibrating body 91 may be brought into contact with an upper surface of the holder 94. The flange 91b may be attached to the holder 94 by using a fastening member such as a screw.

Further, the holder 94 may be movable in the direction parallel to the front surface 100b of the substrate 100. For example, a swivel shaft may be provided in a vicinity of an end portion of the holder 94, which is on an opposite side to a side on which the vibrating body 91 is provided, to swivel the holder 94 that holds the vibrating body 91. For example, in the thawing process to be described later, the holder 94 is swiveled to locate the vibrating body 91 above the front surface 100b of the substrate 100. In another process, the holder 94 is swiveled to move the vibrating body 91 to a retracted position outside the substrate 100.

The cover 95 is provided on the upper surface of the holder 94. The cover 95 covers the vibrator 92. The cover 95 may be attached to the holder 94 by using a fastening member such as a screw.

The controller 10 controls operations of individual components provided in the substrate processing apparatus 1. The controller 10 includes, for example, a calculation part such as a central processing unit (CPU) and a storage such as a semiconductor memory. The controller 10 is, for example, a computer. A control program that controls operations of individual components provided in the substrate processing apparatus 1 is stored in the storage. The calculation part sequentially performs a preliminary process, a liquid film forming process, a cooling process, a thawing process, and a drying process, which will be described later, based on the control program stored in the storage.

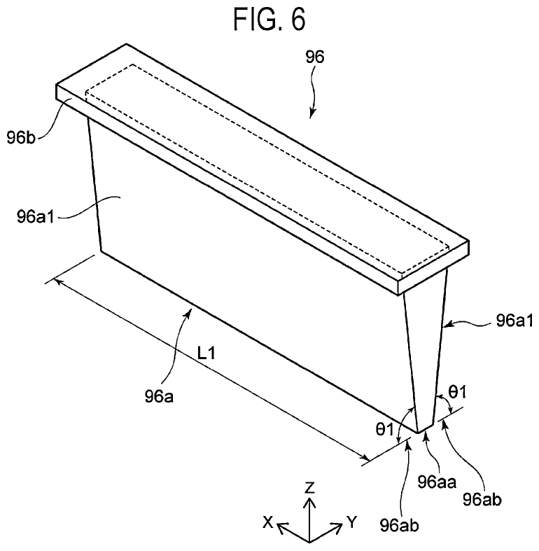

FIG. 6 is a schematic perspective view of a vibrating body 96 according to another embodiment.

In addition, arrows X, Y, and Z in FIG. 6 are the same as in FIG. 2.

As illustrated in FIG. 6, the vibrating body 96 includes, for example, a main body 96a and a flange 96b. The main body 96a and the flange 96b are formed as a single body. A material of the vibrating body 96 may be the same as the material of the above-described vibrating body 91.

The flange 96b may have the same configuration as the above-described flange 91b.

A dimension L1 of the main body 96a in the X direction may be the same as the dimension L of the above-described main body 91a. A side surface 96a1 of the main body 96a in the Y direction is connected to an end portion 96aa of the vibrating body 96 (the main body 96a). The side surface 96a1 is inclined with respect to the end portion 96aa of the vibrating body 96 (the main body 96a). An angle θ1 between the side surface 96a1 of the main body 96a and an extension line 96ab of the end portion 96aa of the vibrating body 96 (the main body 96a) may be the same as the above-described angle θ.

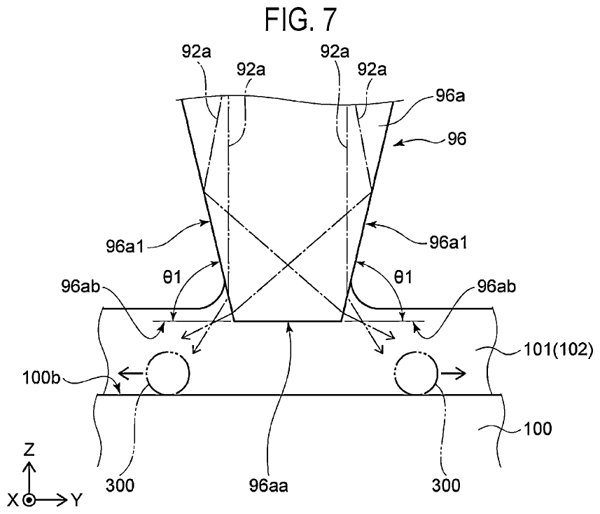

FIG. 7 is a schematic cross-sectional view illustrating an operation of the vibrating body 96.

As illustrated in FIG. 7, in the vibrating body 96, vibrations 92a from the vibrator 92 propagate inside the vibrating body 96 (the main body 96a) and are incident to the side surface 96a1. In a region of the side surface 96a1, which is not in contact with the liquid 101 or 102 (a region in contact with outside air), total reflection easily occurs due to Snell's law. Therefore, in the region of the side surface 96a1, which is not in contact with the liquid 101 or 102, the vibrations 92a propagate while repeating reflection. For example, in FIG. 7, vibrations 92a incident obliquely from above with respect to the Z direction to the side surface 96a1 are vibrations reflected once from the side surface 96a1. A vicinity of the end portion 96aa of the vibrating body 96 (the main body 96a) is in contact with the liquid 101 or 102. For example, the vicinity of the end portion 96aa of the vibrating body 96 (the main body 96a) may be inserted into the liquid 101 or 102. By surface tension of the liquid 101 or 102 or a flow of the liquid 101 or 102 along with the rotation of the substrate 100, the liquid 101 or 102 may be brought into contact with the vicinity of the end portion 96aa of the vibrating body 96 (the main body 96a). The vibrations 92a incident to a portion of the side surface 96a1, which is in contact with the liquid 101 or 102, are easily emitted from the vibrating body 96 (the main body 96a) by Snell's law. In this case, a propagation direction of the vibrations 92a changes according to an inclined angle.

Further, as illustrated in FIG. 7, vibrations 92a, which are emitted from the vibrating body 96 (the main body 96a) without being reflected even once from the side surface 96a1, also exist. For example, in FIG. 7, vibrations 92a incident from above in a direction parallel with the Z direction to the side surface 96a1 are the vibrations 92a emitted from the vibrating body 96 (the main body 96a) without being reflected even once from the side surface 96a1.

Therefore, as illustrated in FIG. 7, a direction of a force acting on the contaminants 300 easily becomes a direction inclined with respect to the front surface 100b of the substrate 100. Accordingly, as explained with respect to FIG. 4, since a component force in a direction parallel to the front surface 100b of the substrate 100 acts on the contaminants 300, the contaminants 300 easily move in the direction parallel to the front surface 100b of the substrate 100. When the contaminants 300 easily move in the direction parallel to the front surface 100b of the substrate 100, it is possible to improve the removal rate of the contaminants 300.

In the case of the vibrating body 96 according to the present embodiment, the side surface 96a1 as an inclined surface is in contact with the liquid 101 or 102 and becomes a region inclined with respect to the end portion 96aa of the vibrating body 96.

In addition, the groove 91a1 having the above-described inclined surface may be provided in the end portion 96aa of the vibrating body 96 (the main body 96a). In addition, the side surface of the above-described vibrating body 91 (the main body 91a) may be an inclined surface.

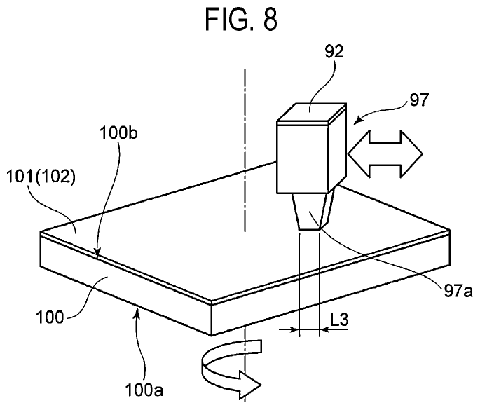

FIG. 8 is a schematic perspective view illustrating a vibrating body 97 according to another embodiment.

As illustrated in FIG. 8, the vibrating body 97 has a side surface 97a inclined with respect to an end portion of the vibrating body 97. For example, the vibrating body 97 may be obtained by reducing the dimension L1 of the above-described vibrating body 96. Further, the vibrating body 97 may be obtained by reducing the dimension L of the above-described vibrating body 91. A dimension L3 of the vibrating body 97 may be smaller than a minimum dimension between the rotational center of the substrate 100 and the periphery of the substrate 100. With this configuration, it is possible to promote miniaturization or cost reduction of the vibrating body 97. However, when the dimension L3 is small, vibrations are transmitted to a partial region of the liquid 101 or 102. Therefore, it is necessary to move a position of the vibrating body 97 between the rotational center of the substrate 100 and the periphery of the substrate 100. For example, the vibrating body 97 may be attached to a holder which is movable in the direction parallel to the front surface 100b of the substrate 100.

Next, the operation of the substrate processing apparatus 1 will be described again.

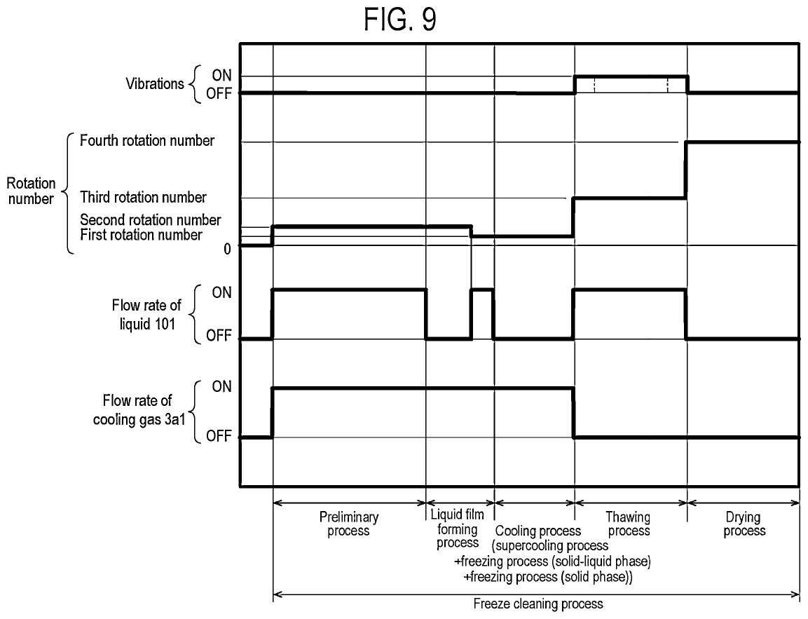

FIG. 9 is a timing chart illustrating an operation of the substrate processing apparatus 1.

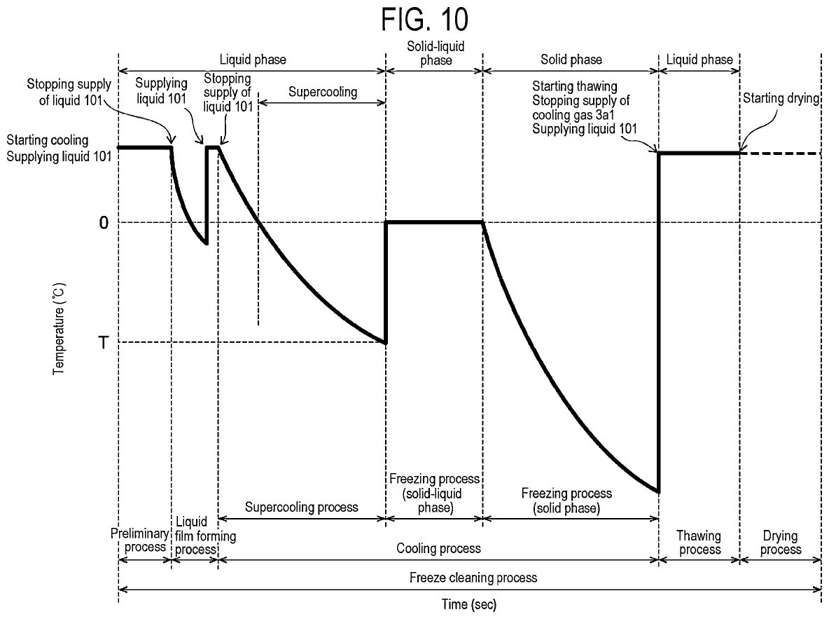

FIG. 10 is a graph illustrating a change in temperature of the liquid 101 supplied to the front surface 100b of the substrate 100.

Further, FIGS. 9 and 10 show a case where the substrate 100 is a 6025 quartz (Qz) substrate (152 mmx 152 mm×6.35 mm), and the liquid 101 and the liquid 102 are pure water.

In addition, the liquid 102 used for thawing is the same as the liquid 101 used for forming the liquid film. Therefore, in FIGS. 9 and 10, the liquid 101 is used even in the thawing process.

First, the substrate 100 is loaded into the chamber 6 via a load/unload port (not illustrated) of the chamber 6. The loaded substrate 100 is placed and supported on the plurality of supports 2a1 of the placement table 2a.

After the substrate 100 is supported on the placement table 2a, a freeze cleaning process including a preliminary process, a liquid film forming process, a cooling process, a thawing process, and a drying process is performed as illustrated in FIGS. 9 and 10.

First, the preliminary process is performed as illustrated in FIGS. 9 and 10.

In the preliminary process, the controller 10 controls the supply 4b and the flow rate controller 4c to supply a predetermined flow rate of the liquid 101 to the front surface 100b of the substrate 100. Further, the controller 10 controls the flow rate controller 3c to supply a predetermined flow rate of the cooling gas 3a1 to the rear surface 100a of the substrate 100. Further, the controller 10 controls the drive 2c to rotate the substrate 100 at a second rotation number.

Here, when the cooling gas 3a1 is supplied and an internal atmosphere of the chamber 6 is cooled, frost containing dust in the atmosphere adheres to the substrate 100, which may cause contamination. Therefore, in the preliminary process, the liquid 101 is continuously supplied to the front surface 100b of the substrate 100. That is, in the preliminary process, while cooling the substrate 100, the frost is prevented from adhering to the front surface 100b of the substrate 100.

The second rotation number is, for example, about 50 rpm to about 500 rpm. The flow rate of the liquid 101 is, for example, about 0.1 L/min to about 1.0 L/min. The flow rate of the cooling gas 3a1 is, for example, about 40 NL/min to about 200 NL/min. A process time of the preliminary process is about 1,800 seconds.

Since the liquid 101 is continuously supplied, a temperature of the liquid film in the preliminary process becomes almost the same as a temperature of the supplied liquid 101. For example, when the temperature of the supplied liquid 101 is about room temperature (e.g., 20 degrees C.), the temperature of the liquid film becomes about room temperature (e.g., 20 degrees C.).

Subsequently, the liquid film forming process is performed as illustrated in FIGS. 9 and 10.

In the liquid film forming process, the supply of the liquid 101 supplied in the preliminary process is stopped. Since the rotation of the substrate 100 is maintained, the liquid 101 on the front surface 100b of the substrate 100 is discharged. In this case, the rotation number of the substrate 100 is reduced to a first rotation number that can suppress a change in thickness of the liquid film due to a centrifugal force. The first rotation number is, for example, 0 rpm to 50 rpm.

After the rotation number of the substrate 100 is set to the first rotation number, the liquid film is formed by supplying a predetermined amount of the liquid 101 to the substrate 100. A thickness of the liquid film (a thickness of the liquid film when performing the cooling process) is, for example, about 300 μm to about 1,300 μm.

Further, during the liquid film forming process, a flow rate of the cooling gas 3a1 is maintained to be the same flow rate as in the preliminary process. In the above-described preliminary process, an in-plane temperature of the substrate 100 is substantially uniform. In the liquid film forming process, when the flow rate of the cooling gas 3a1 is maintained to be the same flow rate as in the preliminary process, a state in which the in-plane temperature of the substrate 100 is substantially uniform can be maintained.

Subsequently, the cooling process is performed as illustrated in FIGS. 9 and 10.

In addition, in this specification, the cooling process includes a “supercooling process,” a “freezing process (solid-liquid phase),” and a “freezing process (solid phase).” The “supercooling process” is a process in which the liquid 101 enters a supercooled state, and continues until the liquid 101 in the supercooled state is started to be frozen. In the supercooling process, only the liquid 101 exists on the entire front surface 100b of the substrate 100. The “freezing process (solid-liquid phase)” is a process from the start of the freeze of the liquid 101 in the supercooled state to a complete end of the freeze. In the freezing process (solid-liquid phase), the liquid 101 and the frozen liquid 101 exist on the entire front surface 100b of the substrate 100. The “freezing process (solid phase)” is a process after the liquid 101 is completely frozen. In the freezing process (solid phase), only the frozen liquid 101 exists on the entire front surface 100b of the substrate 100. Further, in this specification, a completely frozen liquid film is referred to as the frozen film 101a.

In addition, after the liquid film forming process, the freezing process (solid-liquid phase) may be performed without going through the supercooling process to perform the thawing process before the frozen film 101a. Further, after the liquid film forming process, the freezing process (solid-liquid phase), the freezing process (solid phase), and the thawing process may be sequentially performed without going through the supercooling process. That is, the supercooling process and the freezing process (solid phase) may be omitted. Even when the supercooling process and the freezing process (solid phase) are omitted, it is possible to separate the contaminants 300 from the front surface 100b of the substrate 100. When the supercooling process and the freezing process (solid phase) are omitted, it is possible to promote simplifying the cooling process, and further, shortening a required time for the cooling process.

In the supercooling process, by the cooling gas 3a1 continuously supplied to the rear surface 100a of the substrate 100, a temperature of the liquid film on the front surface 100b of the substrate 100 becomes lower than a temperature of the liquid film in the liquid film forming process, so that the liquid 101 enters the supercooled state. In this case, when a cooling speed of the liquid 101 is excessively high, the liquid 101 does not enter the supercooled state, but is frozen directly. Therefore, the controller 10 controls at least one of the rotation number of the substrate 100, the flow rate of the cooling gas 3a1, or the flow rate of the liquid 101 so that the liquid 101 on the front surface 100b of the substrate 100 enters the supercooled state.

A control condition under which the liquid 101 enters the supercooled state is influenced by a size of the substrate 100, a viscosity of the liquid 101, a specific heat of the cooling gas 31a, and the like. Therefore, the control condition under which the liquid 101 enters the supercooled state may be appropriately determined by performing experiments or simulations.

In addition, as described above, the supercooling process may not be performed. In this case, the controller 10 controls at least one of the rotation number of the substrate 100, the flow rate of the cooling gas 3a1, or the flow rate of the liquid 101 so that the cooling speed of the liquid 101 becomes high. By setting the cooling speed of the liquid 101 to be high, the freezing process (solid-liquid phase) is performed without going through the supercooling process.

When the freeze of the liquid 101 in the supercooling state is started, transition is made from the supercooling process to the freezing process (solid-liquid phase). In the supercooled state, the freeze of the liquid 101 is started by, for example, the temperature of the liquid film, existence of the contaminants 300 such as particles or bubbles, vibrations, and the like. For example, when the contaminants 300 such as particles exist, the liquid 101 is started to be frozen when a temperature T of the liquid 101 is-35 degrees C. or higher and −20 degrees C. or lower. Further, the liquid 101 may be started to be frozen by changing the rotation of the substrate 100 or applying vibrations to the liquid 101.

As described above, in the liquid 101 in the supercooled state, the contaminants 300 serve as several percentages of starting points of the freeze. The contaminants 300 serving as the starting points of the freeze are introduced into the frozen film 101a. Therefore, when the supercooling process is performed, it is possible to increase the removal rate of the contaminants 300. In addition, it is considered that the contaminants 300 adhering to the front surface 100b of the substrate 100 are separated by a pressure wave accompanying a change in volume when the liquid 101 is changed into a solid, a physical force accompanying an increase in volume, or the like.

Subsequently, the thawing process is performed as illustrated in FIGS. 9 and 10.

Starting the thawing process may be determined by an elapse time from a start time point of the preliminary process or a start time point of the freezing process (solid-liquid phase). By a length of the elapse time, it is determined whether the thawing is started during the freezing process (solid-liquid phase) or during the freezing process (solid phase). Further, a surface state of the liquid 101 (the frozen film 101a) on the front surface 100b of the substrate 100 may be detected by a detector or the like to determine a timing of starting the thawing from a change in the surface state.

In addition, details of the thawing process will be described later.

Subsequently, the drying process is performed as illustrated in FIGS. 9 and 10.

In the drying process, the controller 10 controls the supply 4b and the flow rate controller 4c to stop the supply of the liquid 101. Further, when the liquid 101 and the liquid 102 are different liquids, the controller 10 controls the supply 5b and the flow rate controller 5c to supply the supply of the liquid 102.

Further, the controller 10 controls the flow rate controller 3c to stop the supply of the cooling gas 3a1.

Further, the controller 10 controls the circuit 93 to stop the generation of the vibrations 92a. Further, the controller 10 may control the holder 94 to move the vibrating body 91, 96 or 97 to the retracted position outside the substrate 100.

Further, the controller 10 controls the drive 2c so that the rotation number of the substrate 100 is set as a fourth rotation number, which is greater than a rotation number (a third rotation number to be described later) of the substrate 100 in the thawing process. When the rotation of the substrate becomes fast, it is possible to reduce a drying time of the substrate 100. In addition, the fourth rotation number is not particularly limited as long as the drying can be performed.

As described above, the freeze cleaning process ends. Further, the freeze cleaning process may be performed a plurality of times.

The substrate 100 having been subjected to the freezing cleaning process is unloaded to the outside of the chamber 6 via the load/unload port (not illustrated).

Next, the thawing process will be described again.

In the thawing process, the controller 10 controls the supply 4b and the flow rate controller 4c to supply the liquid 101 to the frozen film 101a. Further, when the liquid 101 and the liquid 102 are different from each other, the controller 10 controls the supply 5b and the flow rate controller 5c to supply the liquid 102 to the frozen film 101a.

The flow rate of the liquid 101 or the liquid 102 is not particularly limited as long as the thawing can be performed. The temperature of the liquid 101 or the liquid 102 may be set to the room temperature (e.g., 20 degrees C.). Further, as described above, the temperature of the liquid 101 used for forming the liquid film may be set to the room temperature (e.g., 20 degrees C.), and the temperature of the liquid 102 used for the thawing may be set to a temperature exceeding the room temperature.

In addition, the controller 10 controls the drive 2c to increase the rotation number of the substrate 100 from the first rotation number to the third rotation number. The third rotation number is, for example, about 200 rpm to about 700 rpm. When the rotation of the substrate 100 becomes fast, the liquid 101 and the frozen liquid 101 can be shaken off by a centrifugal force. Therefore, it becomes easy to discharge the liquid 101 and the frozen liquid 101 from the front surface 100b from the substrate 100. At this time, the contaminants 300 separated from the front surface 100b of the substrate 100 are also discharged together with the liquid 101 and the frozen liquid 101.

Further, the controller 10 controls the circuit 93 to generate the vibrations 92a from the vibrator 92. The generated vibrations 92a are transmitted to the liquid 101 or 102 via the vibrating body 91, 96 or 97. As illustrated in FIG. 9, a timing at which the vibrations 92a are transmitted may be the same as the start of supplying the liquid 101 or 102 used for the thawing, or may be after the start of supplying the liquid 101 or 102 as indicated by an alternated long and short dash line in FIG. 9. A timing at which the vibrations 92a are stopped may be the same as the stop of supplying the liquid 101 or 102 used for the thawing, or may be before the stop of supplying the liquid 101 or 102 as indicated by an alternated long and short dash line in FIG. 9.

### (Substrate Processing Apparatus According to Second Embodiment)

A substrate processing apparatus 200 according to a second embodiment may be used, for example, when spin-cleaning the substrate 100.

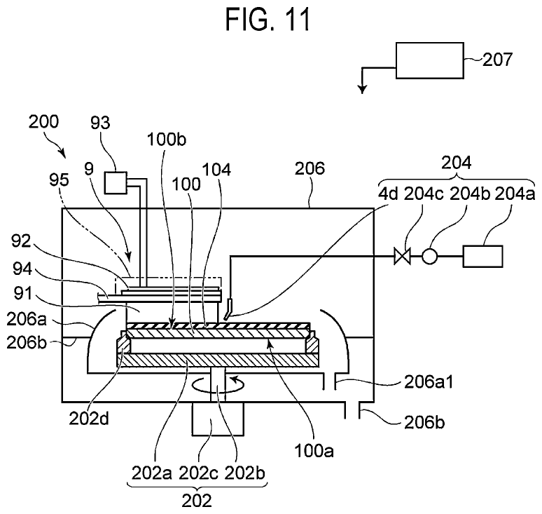

FIG. 11 is a schematic view illustrating the substrate processing apparatus 200 according to the second embodiment.

As illustrated in FIG. 11, the substrate processing apparatus 200 includes, for example, a stage 202, a liquid supply 204, a chamber 206, the vibration generator 9, and a controller 207.

The stage 202 includes, for example, a placement table 202a, a rotary shaft 202b, and a drive 202c.

The stage 202a may have the same configuration as the above-described stage 2a.

However, it is unnecessary to provide the hole 2aa in the placement table 202a. A plurality of supports 202d for supporting the substrate 100 is provided on one main surface of the placement table 202a. When supporting the substrate 100 by the plurality of supports 202d, the front surface 100b (the surface on a side on which cleaning is performed) of the substrate 100 faces a side opposite to the placement table 202a.

One end portion of the rotary shaft 202b is provided on a side of the placement table 202a, which is opposite to a side where the supports 202d are provided. The other end portion of the rotary shaft 202b is provided outside the chamber 206. The rotary shaft 202b is connected to the drive 202c at a location outside the chamber 206.

The drive 202c is provided outside the chamber 206. The drive 202c is connected to the rotary shaft 202b. A rotational force of the drive 202c is transmitted to the placement table 202a via the rotary shaft 202b. Therefore, the placement table 202b, and further, the substrate 100 placed on the placement table 202a, can be rotated by the drive 202c.

Further, the drive 202c may change a rotation number (rotational speed) in addition to start and stop of the rotation. The drive 202c may be provided with, for example, a control motor such as a servo motor.

The liquid supply 204 includes, for example, a liquid accommodator 204a, a supply 204b, a flow rate controller 204c, and a liquid nozzle 4d. The liquid accommodator 204a, the supply 204b, and the flow rate controller 204c are provided outside the chamber 206.

The liquid accommodator 204a accommodates a liquid 104. The liquid 104 may be, for example, SPM, APM, SC-1, HPM, DHF, O₃ (ozone) water, NH₄OH, TMAH, a surfactant, or the like. However, the liquid 104 is not limited to those exemplified above.

The supply 204b supplies the liquid 104 accommodated in the liquid accommodator 204a toward the liquid nozzle 4d. The supply 204b may be, for example, a pump having a resistance to the liquid 104, or the like.

The flow rate controller 204c controls a flow rate of the liquid 104 supplied by the supply 204b. The flow rate controller 204c may be, for example, a flow rate control valve. Further, the flow rate controller 204c may perform start and stop of supplying the liquid 104.

The chamber 206 has a box shape. A cup 206a is provided inside the chamber 206. The cup 206a receives the liquid 104, which is supplied to the substrate 100 and discharged to the outside of the substrate 100 by the rotation of the substrate 100. The cup 206a is installed inside the chamber 206 by a holder 206b. The cup 206a is provided with a discharge port 206a1 for discharging the used liquid 104, which is discharged from the substrate 100, to the outside of the cup 206a. Further, a discharge port 206c for discharging the used liquid 104, which is discharged from the cup 206a, to the outside of the chamber 206 is provided in a bottom surface of the chamber 206.

The controller 207 controls operations of individual components provided in the substrate processing apparatus 200. The controller 207 may have the same configuration as the above-described controller 10. A control program that controls operations of individual components provided in the substrate processing apparatus 200 is stored in a storage of the controller 207. The control program stored in the storage of the controller 10 described above is a program for executing freeze cleaning. On the contrary, the control program stored in the storage of the controller 207 is a program for executing spin cleaning. Further, known techniques may be applied to a sequence, a condition, or the like of the spin cleaning. Thus, detailed descriptions thereof will be omitted.

The vibration generator 9 transmits vibrations to the liquid 104 on the front surface 100b of the substrate 100. Operative effects when the vibration generator 9 transmits vibrations to the liquid 104 may be the same as the operative effects when vibrations are transmitted to the liquid 101 or 102. Therefore, the contaminants 300 easily move in a direction parallel to the front surface 100b of the substrate 100. When the contaminants 300 easily move in the direction parallel to the front surface 100b of the substrate 100, it is possible to improve the removal rate of the contaminants 300. In addition, any one of the vibrating body 91, the vibrating body 96, and the vibrating body 97 may be used.

Further, in the above-described substrate processing apparatus 1 or 200, the vibrating body 91 or 97 is provided on a side of the front surface 100b of the substrate 100, but the vibrating body 91 or 97 may be provided on a side of the rear surface 100a of the substrate 100.

### (Substrate Processing Apparatus According to Third Embodiment)

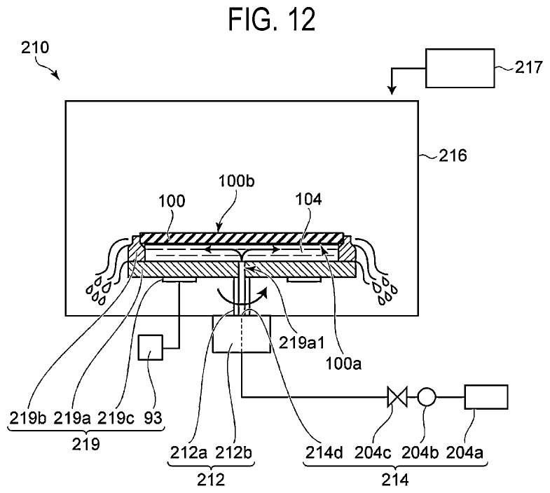

FIG. 12 is a schematic view illustrating a substrate processing apparatus 210 according to a third embodiment.

As illustrated in FIG. 12, the substrate processing apparatus 210 include, for example, a vibration generator 219, a drive 212, a liquid supply 214, a chamber 216, and a controller 217.

The vibration generator 219 includes, for example, a vibrating body 219a, supports 219b, a vibrator 219c, and the circuit 93.

The vibrating body 219a is provided on a side of the rear surface 100a of the substrate 100. The vibrating body 219a has, for example, a plate shape. The vibrating body 219a is, for example, provided rotatably inside the chamber 216. A shape of the vibrating body 219a may be, for example, the same as the shape of the above-described placement table 2a. A hole 219a1 penetrating the vibrating body 219a in a thickness direction is provided in a central portion of the vibrating body 219a. Further, the vibrating body 219a is formed of a material that easily propagates vibrations from the vibrator 219c and hardly generates particles. The vibrating body 219a is formed of, for example, quartz.

The plurality of supports 219b is provided on one main surface of the vibrating body 219a. The supports 219b may have the same configuration as the above-described supports 2a1.

The vibrator 219c is provided on the other main surface of the vibrating body 219a. The vibrator 219c may adhere to the other main surface of the vibrating body 219a. The vibrator 219c may have, for example, an annular shape, and may be provided concentrically with the vibrating body 219a. The vibrator 219c converts an applied voltage into a force. The vibrator 219c is, for example, piezoelectric element or the like.

Further, the vibrator 219c rotates together with the vibrating body 219a. Thus, the vibrator 219c and the circuit 93 may be electrically connected to each other by, for example, a slip ring or the like.

The drive 212 includes, for example, a rotary shaft 212a and a rotary drive 212b.

One end portion of the rotary shaft 212a is provided on a side of the vibrating body 219a, which is opposite to a side where the support 219b is provided. The other end portion of the rotary shaft 212a is provided outside the chamber 216. The rotary shaft 212a is connected to the rotary drive 212b at a location outside the chamber 216.

The rotary drive 212b is provided outside the chamber 216. The rotary drive 212b is connected to the rotary shaft 212a. A rotational force of the rotary drive 212b is transmitted to the vibrating body 219a via the rotary shaft 212a. Thus, the vibrating body 219a, and further the substrate 100 placed on the vibrating body 219a, can be rotated by the rotary drive 212b.

Further, the rotary drive 212b may change a rotation number (rotational speed) in addition to start and stop of the rotation. The rotary drive 212b may be provided with, for example, a control motor such as a servo motor.

The liquid supply 214 includes, for example, a liquid accommodator 204a, a supply 204b, a flow rate controller 204c, and a liquid nozzle 214d.

One end portion of the liquid nozzle 214d may be, for example, provided in the hole 219a1 of the vibrating body 219a. The other end portion of the liquid nozzle 214d may be, for example, connected to the flow rate controller 204c at a location outside the chamber 216.

The liquid nozzle 214d may be integrated with the vibrating body 219a. That is, the vibrating body 219a may be a part of the liquid nozzle 214d. In this case, the liquid nozzle 214d rotates together with the vibrating body 219a. Thus, the liquid nozzle 214d and the flow rate controller 204c may be connected to each other via a rotary joint or the like.

The chamber 216 may have, for example, the same configuration as the above-described chamber 206.

The controller 217 controls operations of individual components provided in the substrate processing apparatus 210. The controller 217 may have the same configuration as the above-described controller 10.

Next, operative effects of the substrate processing apparatus 210 will be described.

The substrate processing apparatus 210 performs cleaning the rear surface 100a of the substrate 100. The liquid 104 is supplied from the liquid nozzle 214d to a space between the rear surface 100a of the substrate 100 and the vibrating body 219a. The space between the rear surface 100a of the substrate 100 and the vibrating body 219a is filled by the liquid 104.

The vibration generator 219 (the vibrating body 219a) transmits vibrations to the liquid 104 between the rear surface 100a of the substrate 100 and the vibrating body 219a. Thus, it is possible to obtain the same operative effects as when vibrations are transmitted to the above-described liquid 101 or 102. That is, the contaminants 300 easily move in a direction parallel to the rear surface 100a of the substrate 100. When the contaminants 300 easily move in the direction parallel to the rear surface 100a of the substrate 100, it is possible to increase the removal rate of the contaminants 300.

In addition, the above-described groove 91a1 may be provided in a surface of the vibrating body 219a, which faces the rear surface 100a of the substrate 100.

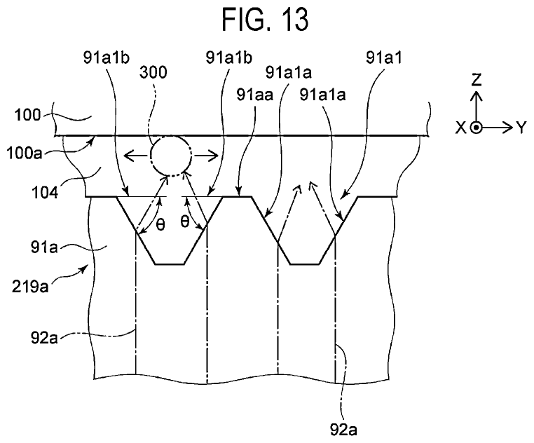

FIG. 13 is a schematic view illustrating the side surface 91a1a of the groove 91a1 provided in the vibrating body 219a.

In addition, arrows X, Y, and Z in FIG. 13 are the same as in FIG. 4.

The groove 91a1 provided in the vibrating body 219a may be provided to have the same shape and the same inclination as the groove 91a1 provided in the above-described vibrating body 91. Thus, it is possible to obtain the same operative effects as the above-described vibrating body 91.

Further, the grooves 91a1 provided in the vibrating body 219a may be provided concentrically with the hole 219a1 of the vibrating body 219a as a center.

Further, in FIG. 13, a case where a contour of a cross-section of the groove 91a1 is a trapezoid is illustrated, but the contour of the cross-section of the groove 91a1 may be, for example, a triangle. Further, the side surface of the groove 91a1 may be a flat surface or a curved surface. When the side surface of the groove 91a1 is the curved surface, an angle between a tangent of the curved surface and an extension line of the end portion 91aa of the vibrating body 219a may be set to θ.

In addition, an opening of the hole 219a1 of the vibrating body 219a on a side of the substrate 100 may have a concave shape. The groove 91a1 may be provided in an inner wall of the concave-shaped opening of the hole 219a1. The liquid 104 supplied from the hole 219a1 is stored in the concave-shaped opening, and at least a partial region of the rear surface 100a of the substrate 100 is immersed in the liquid 104. With this configuration, the supplied liquid 104 is easily held.

Further, in addition to the vibration generator 219, the above-described vibration generator 9 may be provided. That is, the vibration generator may be provided on at least one side of the front surface 100b of the substrate 100 or the rear surface 100a of the substrate 100.

In addition, a stage may not be rotated. In this case, the drive 212 may be omitted.

In the above, the embodiments have been illustrated. However, the present disclosure is not limited to the above-described techniques. The above-described embodiments to which addition, deletion, or design change of elements, or addition, omission, or condition change of processes is appropriately applied by those skilled in the art are also encompassed within the scope of the present disclosure as long as they fall within the spirit of the present disclosure.

For example, a shape, dimension, arrangement, and the like of each element included in the substrate processing apparatus 1, 200, or 210 are not limited to those exemplified above, but may be appropriately changed.

According to one embodiment of the present disclosure, there is provided a vibrating body and a substrate processing apparatus, which facilitate movement of contaminants in a direction parallel to a surface of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A vibrating body for use in cleaning a substrate, comprising:
a contact portion with a liquid on a surface of the substrate,
wherein the contact portion has an inclined region inclined with respect to an end portion of the vibrating body facing the substrate, and
wherein an angle between the inclined region and an extension line of the end portion of the vibrating body is θ, which satisfies the following condition: 20 degrees≤θ≤87 degrees.

2. The vibrating body of claim 1, wherein the inclined region is at least one of a side surface of a groove that is open in the end portion of the vibrating body, or a side surface of the vibrating body connected to the end portion of the vibrating body.

3. The vibrating body of claim 1, wherein the cleaning the substrate is freeze-cleaning the substrate or spin-cleaning the substrate.

4. A substrate processing apparatus, comprising:
a stage configured to rotate a substrate placed on the stage;
a first liquid supply configured to supply a first liquid to a first surface of the substrate, which is on an opposite side to the stage; and
the vibrating body of claim 1,
wherein the vibrating body transmits vibrations to the first liquid on the first surface of the substrate from a direction intersecting the first surface of the substrate, and
wherein the vibrating body is disposed to face a region between a rotational center and a periphery of the substrate placed on the stage.

5. The substrate processing apparatus of claim 4, wherein when the substrate has a circular planar shape, the end portion of the vibrating body has a length equal to or greater than a radius of the substrate, and
wherein when the substrate has a quadrangular planar shape, the end portion of the vibrating body has a length greater than a half of a diagonal dimension of the substrate.

6. The substrate processing apparatus of claim 5, wherein the inclined region is a side surface of a groove that is open in the end portion of the vibrating body, and the groove is formed to extend in a length direction of the end portion.

7. The substrate processing apparatus of claim 4, wherein the inclined region of the vibrating body is in contact with the first liquid on the first surface of the substrate.

8. The substrate processing apparatus of claim 4, further comprising a cooler configured to supply a cooling gas for cooling the first liquid on the first surface of the substrate.

9. The substrate processing apparatus of claim 8, further comprising:
a second liquid supply configured to supply a second liquid for thawing a frozen film, which is obtained by freezing the first liquid by the cooler; and
a controller configured to control the second liquid supply and the vibrating body,
wherein the controller performs a control to generate vibrations of the vibrating body in the second liquid supplied to the first surface of the substrate by the second liquid supply.

10. A substrate processing apparatus, comprising:
a stage configured to place a substrate on the stage;
a liquid supply configured to supply a liquid to a second surface of the substrate on a side of the stage; and
the vibrating body of claim 1,
wherein the vibrating body transmits vibrations to the liquid on the second surface of the substrate from a direction intersecting the second surface of the substrate, and
wherein the vibrating body is disposed to face a region between a rotational center and a periphery of the substrate placed on the stage.

11. The substrate processing apparatus of claim 10, wherein the liquid is supplied to the second surface of the substrate on the side of the stage via the vibrating body.
